(19) United States
(12) Patent Application Publication
(10) Pub. No.: US 2020/0068730 A1
(43) Pub. Date: Feb. 27, 2020

(54) CIRCUIT BOARD MODULE AND METHOD OF ASSEMBLING CIRCUIT BOARD MODULE

(71) Applicant: DENSO CORPORATION, Kariya-city (JP)

(72) Inventor: Tetsuya KIMATA, Kariya-city (JP)

(21) Appl. No.: 16/548,052

(22) Filed: Aug. 22, 2019

(30) Foreign Application Priority Data
Aug. 23, 2018 (JP) 2018-156146

(51) Int. Cl. H05K 5/00; H05K 7/10; H05K 1/11

(52) U.S. Cl. CPC H05K 5/0069; H05K 1/115; H05K 7/10

(57) ABSTRACT

To provide a circuit board module capable of effectively performing input and output to and from more than two communication ICs by using only one female connector having multiple terminals, the multiple terminals include at least one first terminal 61 connected to a first circuit pattern 83a on a first side 90a of the sensor circuit board 90 and at least one second terminal 62 connected to a second circuit pattern 84a on a second side 90b thereof. The at least one first terminal 61 includes an overlapping portion 50 at its tip to be laid on the first side 90a and is connected to the first circuit pattern 90a thereon. The at least one second terminal 62 includes a penetrating portion 52 at its tip to penetrate the sensor circuit board 90 and is connected to the second circuit pattern 84a on the second side 90b.

### CROSS-REFERENCE TO RELATED APPLICATION

This patent application is based on and claims priority to Japanese Patent Application 2018-156146, filed on Aug. 23, 2018 in the Japan Patent Office, the entire disclosure of which is hereby incorporated by reference herein.

### BACKGROUND

### Technical Field

Embodiments of this disclosure relate to a circuit board module having a connector mounted on any one of sides of the circuit board, and a method of assembling the circuit board module.

### Related Art

A conventional circuit board module is composed of a circuit board and a connector with multiple terminals mounted on the circuit board. Each of the terminals of the connector is physically connected to a circuit pattern formed on the circuit board and is electronically connected to the circuit board via the circuit pattern.

When multiple communication ICs (Integrated Circuits) are mounted on a circuit board and a single connector is shared, wires that connect the communication ICs with the connector are desirably shortest not to cause needless radiation or the like therefrom. However, when the communication ICs are mounted on the same side of the circuit board, all of the wires connecting the connector with the communication ICs cannot always be shortest. As a result, communication quality can vary among communication lines of these wires.

Accordingly, an embodiment of the present disclosure is made in view of the above-described problem, and an object thereof is to provide a novel circuit board module that enables input or output to and from multiple communication ICs via a single connector while precisely performing communications via these terminals of the connector.

### SUMMARY

Accordingly, one aspect of the present disclosure provides a novel circuit board module that includes; a connector that includes at least one first terminal, at least one second terminal, and a grand terminal. The circuit board module also includes a circuit board (90) that holds at least two communication ICs on at least one of a first side and a second side opposite to the first side of the circuit board. The circuit board also holds the connector on the first side (90a) thereof and includes at least two circuit patterns on at least one of the first side and the second side thereof to connect the at least two communication ICs with the connector, respectively. The at least one first terminal includes an overlapping portion at its tip. The overlapping portion is laid on the first side of the circuit board to be connected to one of the at least two circuit patterns on the first side. The at least one second terminal includes a penetrating portion at its tip, the penetrating portion penetrates the circuit board to be connected to the other one of the at least two circuit patterns on the second side of the circuit board.

That is, in the above-described configuration, out of the connector terminals, the first terminal has an overlapping portion at its tip to be able to overlap with the first side and connect with the circuit pattern thereon via the overlapping portion. Further, out of the connector terminals, the second terminal has the penetrating portion at its tip to penetrate the circuit board and connect with the circuit pattern on the second side at the penetrating portion. Thus, when a communication IC is mounted on the first side of the circuit board, on which the connector is implemented, the first terminal can be connected to the circuit pattern on the first side. Also, when a communication IC is mounted on the second side opposite to the first side of the circuit board, the second terminal penetrating the circuit board is connected to the circuit pattern on the second side. Because of this, since circuit patterns connecting the first and second terminals of the connector with the communication ICs can be formed on different surfaces of the circuit board, respectively, a freedom of designing circuit patterns can be increased. As a result, since a difference in quality of communication between multiple communication ICs can be reduced, input and output to and from the multiple communication ICs can be achieved by only one connector, while preferably using the terminals of the connector.

Another aspect of the present disclosure provides a novel circuit board module that includes; a connector having multiple terminals; a first communication IC to perform communication in a first circuit; and a second communication IC to perform communication in a second circuit. The circuit board module further includes a circuit board to hold the connector and the first communication IC on a first side thereof and the second communication IC on a second side opposite to the first side thereof. The circuit board also includes at least two circuit patterns to connect the first and second communication ICs with the connector via the multiple terminals, respectively.

Yet another aspect of the present disclosure provides a novel method of assembling a circuit board module. The method includes the steps of: mounting at least two communication ICs on at least one of a first side and a second side opposite to the first side of a circuit board; mounting a connector on the first side of the circuit board; and connecting the at least two communication ICs with the connector, respectively. The method also includes the steps of: drawing at least two circuit patterns on the first side and the second side of the circuit board, respectively; laying an overlapping portion formed at a tip of the at least one first terminal on the first side of the circuit board; and connecting the overlapping portion with one of the at least two circuit patterns on the first side. The method further includes the steps of: boring a through hole in the circuit board; passing a penetrating portion formed at a tip of the at least one second terminal through the through hole; and connecting to the penetrating portion with the one of the at least two circuit patterns on the second side of the circuit board.

In general, when a connector is shared by communication ICs mounted on both sides of the circuit board to be used in different communication circuits, respectively, because an impedance of wiring that connects the connector with a communication IC mounted on an opposite side to the connector varies, a communication quality via the wiring decreases. In particular, when the communication ICs are mounted on the same side of the circuit board, an area to be able to form the circuit patterns from the terminals of the connector to the respective communication ICs can be limited depending on either a size of an area of the circuit board occupied by the communication ICs or specifications (e.g., a size, a layout of terminals, etc.) of the communication ICs as well. Hence, due to a difference in impedance between the circuit patterns, a difference in communication quality can accordingly be increased as a problem. However, according to the above-described system (i.e., the configuration), the first communication IC is mounted on the first side of the sensor circuit board, and the second communication IC is mounted on the second side of the sensor circuit board. That is, since respective circuit patterns extending from the connector to the first and second communication ICs can be formed on different sides of the sensor circuit board, freedom of designing the circuit patterns can be increased regardless of the size of the area of the circuit board occupied by the first and second communication ICs and any devices needed for communication wiring thereon. As a result, since the difference in communication quality between communications executed by the respective communication ICs can be minimized, a single connector can be preferably used.

### BRIEF DESCRIPTION OF THE DRAWINGS

A more complete appreciation of the present disclosure and many of the attendant advantages of the present disclosure will be more readily obtained as substantially the same becomes better understood by reference to the following detailed description when considered in connection with the accompanying drawings, wherein:

FIG. 1 is a block diagram illustrating an exemplary camera system according to one embodiment of the present disclosure;

FIG. 2 is a diagram illustrating a connection system connecting a connector with a sensor circuit board according to one embodiment of the present disclosure;

FIG. 3 is a diagram illustrating the connector viewed from a second side (i.e., a backside) of the sensor circuit board according to one embodiment of the present disclosure;

FIG. 4 is a plan view partially illustrating the sensor circuit board according to one embodiment of the present disclosure; and

FIG. 5 is a perspective view illustrating a circuit board module of a comparative example.

### DETAILED DESCRIPTION

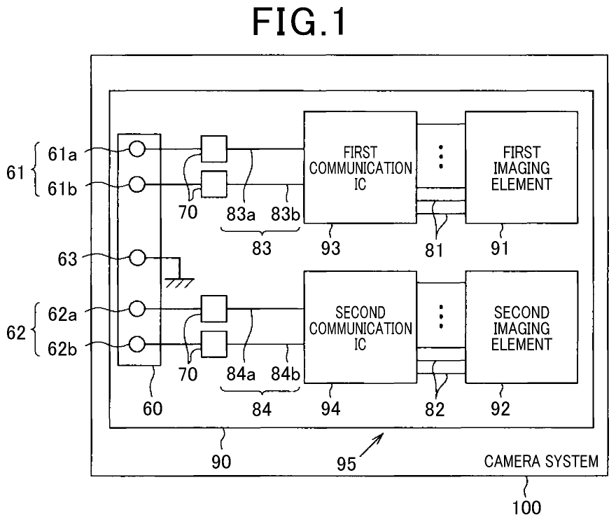

Referring now to the drawings, wherein like reference numerals designate identical or corresponding parts throughout the several views thereof, and to FIG. 1, an exemplary camera system mounted on a vehicle according to a first embodiment of the present disclosure is described. That is, a camera system is installed, for example, in a vehicle to capture an image of surroundings of an own vehicle and outputs image data to a camera ECU (Electric Control Unit).

The camera system 100 of FIG. 1 includes a lens section (not illustrated) that acts as an optical system and a circuit board module 95 that converts light focused by the lens section into an image signal. The circuit board module 95 includes a sensor circuit board 90 of a both-side mounted type, on each of which one or more elements are mountable. For example, a first imaging element 91, a second imaging element 92, and a first communication IC 93 are mounted on the sensor circuit board 90. Also, a second communication IC 94 and a female connector 60 are mounted on the sensor circuit board 90 as well.

Each of the first and second imaging elements 91 and 92 is configured by a well-known imaging element, such as a CCD (Charge Coupled Device), a CMOS (Complementary Metal Oxide Semiconductor), etc., and converts light output from the lens into an image signal.

The first communication IC 93 is connected to the first imaging element 91 through an image input path 81 at one side thereof and is connected to the female connector 60 via a first transmission path 83 at another side thereof. Similarly, the second communication IC 94 is connected to the second imaging element 92 through an image input path 82 at one side thereof and is connected to the female connector 60 via a second transmission path 84 at another side thereof as well. These first and second communication ICs 93 and 94 convert the image signals output from the first and second imaging elements 91 and 92 into signals of an LVDS (Low Voltage Differential Signaling) standard, and output these conversion results through transmission paths 83 and 84, respectively.

The first transmission path 83 is composed of a pair of circuit patterns 83a and 83b formed on the sensor circuit board 90. Similarly, the second transmission path 84 is composed of a pair of circuit patterns 84a and 84b formed on the sensor circuit board 90 as well. A filter circuit 70 is disposed in each of the first and second transmission paths 83 and 84 as shown. The filter circuit 70 is, for example, composed of a capacitance which filters out a DC (Direct Current) component and allows an AC (Alternating Current) component to flow in each of the first and second transmission paths 83 and 84.

In this embodiment of the present disclosure, the female connector 60 is a female connector that includes a recess fitting to a counterpart connector when a tip of the counterpart connector is inserted thereinto. The connector includes a first terminal 61, a second terminal 62 and a ground terminal 63. The first terminal 61 is composed of a pair of first terminal elements 61a and 61b (herein after sometimes collectively referred to as the first terminal 61) corresponding to the pair of circuit patterns 83a and 83b, respectively. The second terminal 62 is also composed of a pair of second terminal elements 62a and 62b (herein after sometimes collectively referred to as the second terminal 62) corresponding to the pair of circuit patterns 84a and 84b, respectively.

The pair of first terminal elements 61a and 61b is connected to the pair of first transmission paths (e.g., circuit patterns) 83a and 83b connected to the first communication IC 93 on the sensor circuit board 90, respectively. Also, the pair of second terminal elements 62a and 62b is connected to the pair of second transmission paths (e.g., circuit patterns) 84a and 84b connected to the second communication IC 94 on the sensor circuit board 90, respectively. The ground terminal 63 is connected to ground to earth the sensor circuit board 90.

An image signal output from the first imaging element 91 is converted into the LVDS standard signal by the first communication IC 93, and is further output to the camera ECU via the pair of first terminal elements 61a and 61b of the female connector 60. Similarly, an image signal output from the second imaging element 92 is converted into an LVDS standard signal by the second communication IC 94, and is further output to the camera ECU via the pair of second terminal elements 62a and 62b of the female connector 60.

In this embodiment of the present disclosure, the camera ECU recognizes an object and detects a position of the object as recognized based on the image data output from the camera system 100.

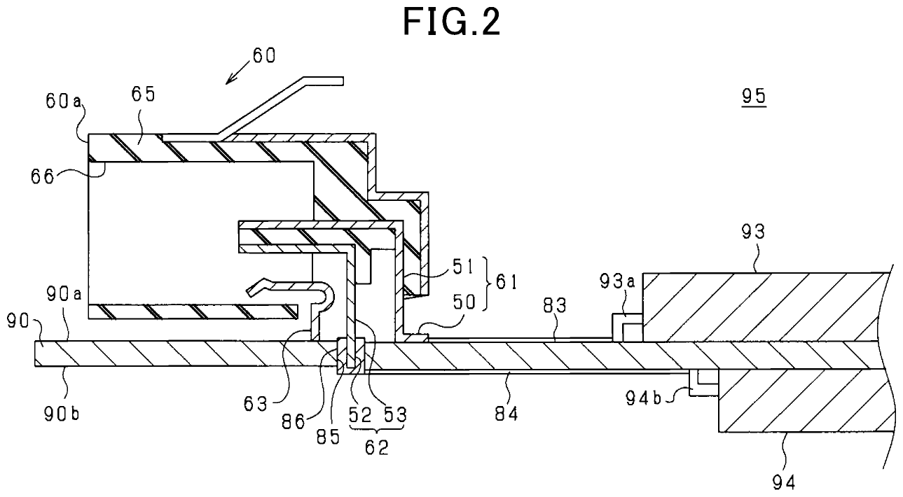

In general, when the single female connector 60 handles signals input and output to and from circuit patterns, formed on respective sides of the sensor circuit board 90, the first terminal 61 is electrically connected to one side of the sensor circuit board 90 on which the female connector 60 is mounted. By contrast, the second terminal 62 is electrically connected to an opposite side to the one side of the sensor circuit board 90 on which the female connector 60 is mounted. Hence, in one comparative example, first and second terminals 61 and 62 are prepared by using a bending molding method to have bends, respectively, as illustrated in FIG. 2. Then, a tip of the first terminal 61 is connected to one end of a transmission path (i.e., a circuit pattern) connected to the first communication IC 93 at its another end on the connector mounting side of the sensor circuit board 90. By contrast, a tip of the second terminal 62 penetrates a through hole (from the connector mounting side of the sensor circuit board 90) and is connected to the transmission path (i.e., another circuit pattern) connected to the communication IC 94 on the opposite side to the connector mounting side. However, when the through hole is interposed in a communication path formed from the second terminal 62 to the second communication IC 94, since the through hole generates an impedance inconsistent with that of the second transmission path 84 composed of a wiring pattern, there exists a risk of degrading communication quality. For example, the inconsistent impedance may deteriorate EMC (electromagnetic compatibility) performance or the like.

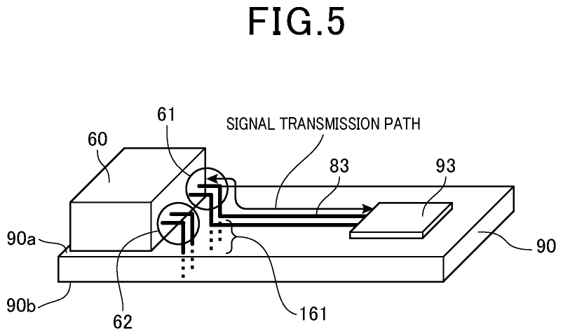

Further, as illustrated in FIG. 5, when both of the first and second terminals 61 and 62 longitudinally penetrate the sensor circuit board 90 from above the sensor circuit board 90, a middle portion of the first terminal 61 in a longitudinal direction is connected to a transmission path (i.e., a circuit pattern) 83 formed on the connector mounting side 90a of the sensor circuit board 90. By contrast, a tip portion of the second terminal 62 in the longitudinal direction is connected to another transmission path (i.e., another circuit pattern) 84 formed on the opposite side 90b to the connector mounting side 90a. In such a situation, however, since a communication path starting from the connector 60 branches off 161 in the middle of the first terminal 61, a signal may reflect at a tip of the first terminal 61, thereby probably degrading a quality of communication again.

Further, as another comparative example, when both of the first and second terminals 61 and 62 are formed linearly and longitudinally penetrate the sensor circuit board 90 from above the sensor circuit board 90, a middle portion of the first terminal 61 in a longitudinal direction is connected to a transmission path (i.e., a circuit pattern) formed on the connector mounting side of the sensor circuit board 90. By contrast, a tip portion of the second terminal 62 in the longitudinal direction is connected to another transmission path (i.e., another circuit pattern) formed on the opposite side to the connector mounting side. In such a situation, however, since a communication path starting from the connector branches off in the middle of the first terminal, a signal may be reflected at a tip of the first terminal, thereby probably degrading the communication quality again.

Hence, according to one embodiment of the present disclosure, difference in communication quality between communications executed through respective first and second terminals 61 and 62 is avoided by differentiating a system of connecting the first terminal 61 to a transmission path (i.e., a circuit pattern) and that of connecting the second terminal 62 to another transmission path (another circuit pattern) from each other.

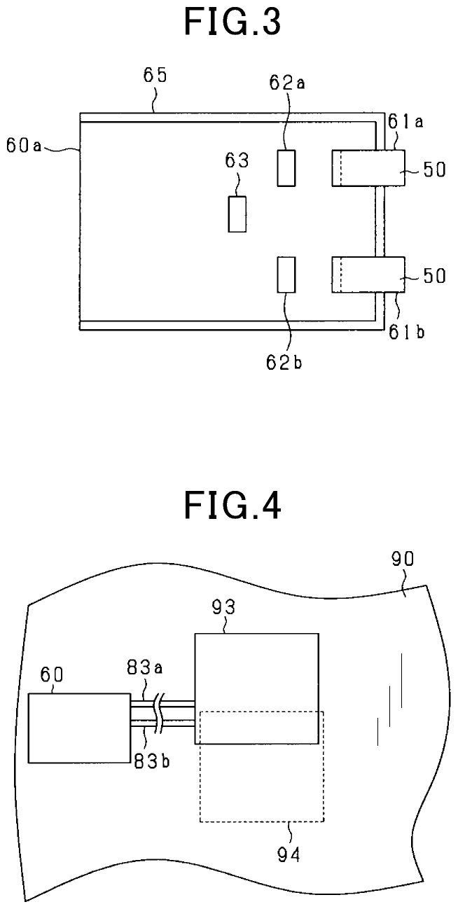

Now, an exemplary sensor circuit board 90, on which first and second communication ICs 93 and 94 and a female connector 60 are mounted is described with reference to FIGS. 2 to 4 according to one embodiment of the present disclosure. FIG. 2 is a diagram schematically illustrating the sensor circuit board 90, on which the female connector 60 is mounted. FIG. 3 is a bottom view schematically illustrating the female connector 60. Herein below, out of respective sides of the sensor circuit board 90, a side on which the female connector 60 is mounted is referred to as a first side 90a, and an opposite side to the side on which the female connector 60 is mounted is referred to as a second side 90b.

As shown in FIG. 2, the female connector 60 according to this embodiment of the present disclosure is composed of a housing 65 as a connector body having a box-shape with an opening of a recess 66 at a prescribed side. The female connector 60 is mounted on the first side 90a of the sensor circuit board 90 to be able receive insertion of a counterpart connector (i.e., a male connector) into the recess 66 in a direction parallel to the first side 90a of the sensor circuit board 90. Specifically, the female connector 60 is mounted on the first side 90a of the sensor circuit board 90 with a plane 60a of the opening of the recess 66 intersecting the first side 90a of the sensor circuit board 90.

Both of the first terminal 61 and the second terminal 62 of the female connector 60 mounted on the sensor circuit board 90 are composed of bus bars, respectively, having substantially the same length with each other. The bus bars extend from a bottom (i.e., a right-side wall in the drawing) of the housing 65 toward the sensor circuit board 90. The first terminal 61 includes an overlapping portion 50 at its tip to overlap with the first side 90a of the sensor circuit board 90. The overlapping portion 50 is configured to connect to the transmission path (i.e., the circuit pattern) formed on the front side 90a. The second terminal 62 includes a linear penetrating portion 52 to penetrate the sensor circuit board 90 at its tip. The penetrating portion 52 is configured to connect to the other transmission path (i.e., the other circuit pattern) formed on the second side 90b as well.

In this embodiment of the present disclosure, the first terminal 61 includes a first base portion 51 extending perpendicular to the first side 90a of the sensor circuit board 90. The overlapping portion 5b is prepared by bending the first base portion 51 at a right angle. The second terminal 62 similarly includes a second base portion 53 extending perpendicular to the first side 90a of the sensor circuit board 90. However, a penetrating portion 52 is provided and linearly extends from a tip of the second base portion 53.

As shown in FIG. 3, the first terminal elements 61a and 61b are aligned with each other parallel to the recess opening plane 60a of the housing 65. Similarly, the second terminal elements 62a and 62b are aligned with each other parallel to the recess opening plane 60a as well. The pair of first terminal elements 61a and 61b and the pair of second terminal elements 62a and 62b are arranged side by side perpendicular to the recess opening plane 60a. Specifically, each of the second terminal elements 62a and 62b is arranged on an opposite side to a tip of the overlapping portion 50 of each of the first terminal elements 61a and 61b.

The ground terminal 63 is also disposed in the female connector 60 on the opposite side to the tip of each of the overlapping portions 50 of the pair of first terminal elements 61a and 61b. The ground terminal 63 is located closer to the recess opening plane 60a than the pair of second terminal elements 62a and 62b are.

As illustrated in FIG. 2, the sensor circuit board 90 includes a pair of through holes 85 (herein below collectively referred to sometimes as a through hole 85), through which the penetrating portions 52 of the second terminal 62 respectively penetrate. Unlike a typical through hole that generally accommodates a tubular conductor on an inner circumferential surface thereof, the through hole 85 of this embodiment of the present disclosure does not accommodate such a conductor. Instead, the through hole 85 of this embodiment of the present disclosure is filled with electrically conductive solder 86 while receiving insertion of the tip of the penetrating portion 52 of the second terminal 62. Further, on the second side 90b of the sensor circuit board 90, a second transmission path 84 is formed and extends up to an opening edge of the through hole 85. Hence, the penetrating portion 52 of the second terminal 62 and the second transmission path 84 formed on the second side 90b are electrically connected to each other via the electrically conductive solder 86.

In this embodiment of the present disclosure, a first transmission path 83 composed of a set of circuit patterns is formed to linearly connect the tips of the overlapping portions 50 of the first terminal 61 to respective input terminals 93a and 93b of the first communication IC 93 on the first side 90a of the sensor circuit board 90. Similarly, the second transmission path 84 is composed of a set of circuit patterns that linearly connect the tips of the penetrating portions 52 of the second terminals 62 to respective input terminals 94a and 94b of the second communication IC 94 on the second side 90b of the sensor circuit board 90.

Further, as shown in FIG. 4, when the circuit board module 95 is viewed from above the first side 90a of the sensor circuit board 90, the first and second communication ICs 93 and 94 are mounted partially overlapping with each other on the first and second sides 90a and 90b of the sensor circuit board 90. That is, in this embodiment of the present disclosure, when the sensor circuit board 90 is viewed from above the first side 90a of the sensor circuit board 90, the first communication IC 93 deviates from a horizontal center line of the female connector 60 to one side in a direction, in which first terminal elements 61a and 61b are aligned with each other (see FIG. 3). By contrast, when the sensor circuit board 90 is viewed from above the first side 90a of the sensor circuit board 90, the second communication IC 94 deviates from the horizontal center line of the female connector 60 to the other side in the direction, in which the first terminal elements 61a and 61b are aligned with each other. Hence, since the first and second communication ICs 93 and 94 overlap with each other on the sensor circuit board 90 in the direction in which the first terminals 61a and 61b are aligned with each other, a length of the sensor circuit board 90 in the direction, in which the first terminals 61a and 61b are aligned with each other can be minimized by an amount of overlapping of these first and second communication ICs 93 and 94.

Now, various advantages obtainable in one embodiment of the present disclosure are herein below described.

First, when the first communication IC 93 is mounted on the first side 90a of the sensor circuit board 90, the first terminal 61 is connected to the first transmission path 83 on the first side 90a, on which the female connector 60 is mounted. Similarly, when the second communication IC 93 is mounted on the second side 90b of the sensor circuit board 90, the second terminal 62 is connected to the second transmission path 84 on the second side 90b opposite the first side 90a, on which the female connector 60 is mounted. For this reason, since the transmission paths 83 and 84 can be formed on the first and second sides 90a and 90b of the sensor circuit board 90, respectively, to connect the first and second terminals 61 and 62 of the female connector 60 with the respective communication ICs 93 and 94a, freedom of designing the first and second transmission paths 83 and 84 may be enhanced. In addition, since the second terminal 62 of the female connector 60 is connected directly to the second transmission path 84 located on the second side 90b without passing through the through hole, impedance mismatch rarely occurs on a communication path starting from the second terminal 62 to the second communication IC 94. Therefore, a difference in communication quality between communication executed by using the first terminal 61 and that executed by using the second terminal 62 may be suppressed. As a result, in a system, in which a single female connector 60 handles signal input and output to and from each of transmission paths 83 and 84 located on the respective sides of the sensor circuit board 90, these transmission paths can be effectively established from terminals 61 and 62 of the female connector 60 to the respective communication ICs 93 and 94.

Further, the first and second terminals 61 and 62 have the respective first and second base portions 51 and 53 composed of bus bars extending perpendicular to the first side 90a having substantially the same length to each other. In addition, the overlapping portion 50 of the first terminal 61 is prepared by bending the first base portion 51 and extending parallel to the first side 90a. Further, the penetrating portion 52 of the second terminal 62 extends from the base portion 53 perpendicular to the plane of the second side 90b of the sensor circuit board 90. Hence, with the above-described configuration that employs the bus bars of substantially the same length as the first and second terminals 61 and 62, respectively, the length of the transmission path between the first terminal 61 and the first transmission path 83 and that between the second terminal 62 and the second transmission path 84 can be substantially equalized. Accordingly, the difference in quality of communication therebetween can be further reduced. Further, in addition to the above-described advantages, according to this embodiment of the present disclosure, the first and second terminals 61 and 62 can be prepared by simple structures, respectively.

Further, the female connector 60 includes the multiple first terminal elements 61a and 61b and the multiple second terminal elements 62a and 62b. The multiple first terminal elements 61a and 61b are aligned with each other in a row, and the multiple second terminal elements 62a and 62b are also aligned with each other in a row as well. In addition, the multiple first terminal elements 61a and 61b are arranged parallel to the multiple second terminal elements 62a and 62b. Further, on the opposite side of the tip of the overlapping portion 50 of the first terminal 61, the second terminal 62 is arranged. Hence, due to the above-described arrangement of the first and second terminals 61 and 62, the female connector 60 can be downsized. Further, interference of the overlapping portion 50 of the first terminal 61 with the second terminal 62 can be either reduced or suppressed.

Further, in general, when a female connector 60 is shared by first and second communication ICs 93 and 94 of different communication circuits, due to an impact of a difference in impedance between circuit patterns extending from the first and second terminals 61 and 62 of the female connector 60 to the respective first and second communication ICs 93 and 94, etc., there is a risk of generating a difference in communication quality between the first and second communication ICs 93 and 94. Further, when the first and second communication ICs 93 and 94 are mounted on the same side of the circuit board, an area to be able to form circuit patterns from the first and second terminals 61 and 62 of the female connector 60 to the respective first and second communication ICs 93 and 94 can be limited depending on a size of an area of the circuit board occupied by the first communication IC 93 and the second communication IC 94. However, according to the above-described embodiment of the present disclosure, the first communication IC 93 is mounted on the first side 90a of the sensor circuit board 90, and the second communication IC 94 is mounted on the second side 90b of the sensor circuit board 90. That is, since respective circuit patterns extending from the female connector 60 to the first and second communication ICs 93 and 94 can be formed on the first and second sides 90a and 90b of the sensor circuit board 90 of different sides, freedom of designing the circuit patterns can be increased. As a result, a difference in communication quality between first and second communications executed by the respective first and second communication ICs 93 and 94 can be minimized.

Now, various modifications of the above-described embodiment of the present disclosure are herein below described. First, in the female connector 60 mounted on the sensor circuit board 90, the first and second terminals 61 and 62 may omit the first and second base portions 51 and 53 respectively extending perpendicular to the first side 90a of the sensor circuit board 90.

Further, the first terminal 61 can be located closer to the recess opening plane 60a of the female connector 60 than the second terminal 62 is. In such a situation, the tip of the overlapping portion 50 of the first terminal 61 can be placed on the same side as the second terminal 62 is located.

Further, a standard of communication between the circuit board module 95 and the camera ECU is not limited to the LVDS and can include other types. In such a situation, each of the first and second communication ICs 93 and 94 can include one first terminal 61 and one second terminal 62 and is connected to the terminals of the female connector 60 via these first and second terminals 61 and 62.

Further, the circuit board module 95 can include more than two first and second communication ICs 93 and 94 as well.

Further, the female connector 60 can be a male connector as well. In such a situation, a female connector is employed as the counterpart connector (i.e., the connector to be coupled).

Further, equipment, on which the circuit board module is mounted is not limited to the camera system, and can include any system if a circuit board is installed therein and a connector is mounted thereon.

Numerous additional modifications and variations of the present disclosure are possible in light of the above teachings. It is therefore to be understood that within the scope of the appended claims, the present disclosure may be executed otherwise than as specifically described herein. For example, the circuit board module is not limited to the above-described various embodiments and may be altered as appropriate. Similarly, the method of assembling a circuit board module is not limited to the above-described various embodiments and may be altered as appropriate.

What is claimed is:

1. A circuit board module, comprising:
a connector (60) having at least one first terminal, at least one second terminal, and a ground terminal (61, 62, 63), and
a circuit board (90) to hold at least two communication ICs (93 and 94) on at least one of a first side (90a) and a second side (90b) opposite to the first side (90a) of the circuit board,
the circuit board holding the connector on the first side (90a) thereof,
the circuit board (90) including at least two circuit patterns (83 and 84) on at least one of the first side (90a) and the second side (90b) thereof to connect the at least two communication ICs (95) with the connector, respectively,
wherein the at least one first terminal includes an overlapping portion (50) at its tip, the overlapping portion disposed on the first side of the circuit board to be connected to one of the at least two circuit patterns on the first side,
wherein the at least one second terminal includes a penetrating portion (52) at its tip, the penetrating portion penetrating the circuit board to be connected to the other one of the at least two circuit patterns on the second side of the circuit board.

2. The circuit board module as claimed in claim 1, wherein each of the at least one first terminal and the at least one second terminal includes a base portion (51 and 53) extending perpendicular to the first side of the circuit board from a body (65) of the connector,
wherein the overlapping portion of the at least one first terminal is prepared by bending the base portion (51) and extending substantially parallel to the first side of the circuit board, wherein the penetrating portion of the at least one second terminal extends from the base portion (53) to intersect the second side of the circuit board.

3. The circuit board module as claimed in claim 1, wherein the circuit board includes at least one through hole (85) to allow the at least one second terminal to penetrate the circuit board, the at least one through hole filled with electric conductor (86),
wherein the penetrating portion is electrically connected to one of the at least two circuit patterns on the second side via the electric conductor.

4. The circuit board module as claimed in claim 1, wherein the at least one first terminal includes at least two first terminals, and the at least one second terminal includes at least two second terminals,
wherein each of the at least two first terminals line up in a first row and each of the at least two second terminals line up in a second row, the first row and the second row being parallel to each other, wherein the at least two second terminals are arranged on an opposite side to a tip side of the overlapping portion of each of the at least two first terminals.

5. A circuit board module, comprising:
a connector (60) having multiple terminals (61, 62, 63);
a first communication IC (93) to perform communication in a first circuit;
a second communication IC (94) to perform communication in a second circuit;
a circuit board (90) to hold the connector and the first communication IC (93) on a first side (90a) thereof and the second communication IC (94) on a second side (90b) opposite to the first side (90a) thereof,
the circuit board including at least two circuit patterns (83 and 84) to connect the first and second communication ICs with the connector via the multiple terminals, respectively.

6. The circuit board module as claimed in claim 5, further comprising at least two imaging elements (91 and 92) to receive and convert light into an image signal, the at least two imaging elements connected to the first and second communication ICs to input the image signals, respectively.

7. A method of assembling a circuit board module, comprising the steps of:
mounting at least two communication ICs (93 and 94) on at least one of a first side (90a) and a second side (90b) opposite to the first side (90a) of a circuit board;
mounting a connector on the first side (90a) of the circuit board;
connecting the at least two communication ICs (95) with the connector, respectively;
drawing at least two circuit patterns (83 and 84) on the first side (90a) and the second side (90b) of the circuit board (90), respectively;
laying an overlapping portion (50) formed at a tip of the at least one first terminal on the first side of the circuit board;
connecting the overlapping portion with one of the at least two circuit patterns on the first side;
boring a through hole in the circuit board;
passing a penetrating portion (52) formed at a tip of the at least one second terminal through the through hole; and
connecting to the penetrating portion with the one of the at least two circuit patterns on the second side of the circuit board.
